(19) United States
(12) Patent Application Publication
(10) Pub. No.: US 2015/0280476 A1
(43) Pub. Date: Oct. 1, 2015

(54) METHOD FOR MONITORING A CHARGE STATE OR A CHARGE OR DISCHARGE CURRENT OF A RECHARGEABLE BATTERY

(71) Applicant: Robert Bosch GmbH, Stuttgart, DE (US)

(72) Inventor: Alexander OSSWALD, Stuttgart (DE)

(21) Appl. No.: 14/675,170

(22) Filed: Mar. 31, 2015

(30) Foreign Application Priority Data
Apr. 1, 2014 (DE) 10 2014 206 112.1

(51) Int. Cl. H02J 7/00; G01R 31/36

(52) U.S. Cl. CPC H02J 7/0052; G01R 31/3606; G01R 31/3648

(57) ABSTRACT

A method is provided for monitoring a charge state or a charge or discharge current of a rechargeable battery, in particular to a charging or discharging process for a rechargeable battery, in particular a rechargeable lithium-ion battery, the charge state or the charge or discharge current of the rechargeable battery being inferred from a derivation (dU/dt) of a charge voltage (U) or discharge voltage (U) of the rechargeable battery. Also provided are a computer program or a computer program product, an arithmetic unit or a processing device, and a rechargeable battery charger or a rechargeable battery-operated device.

### FIELD OF THE INVENTION

The present invention relates to a method for monitoring a charge state or a charge or discharge current of a rechargeable battery, in particular to a charging or discharging process for a rechargeable battery, in particular a rechargeable lithium-ion battery. The present invention further relates to a computer program or a computer program product, to an arithmetic unit or a processing device, and/or to a rechargeable battery charger or a rechargeable battery-operated device.

### BACKGROUND INFORMATION

A growing number of electrical and electronic devices are exclusively or optionally supplied with electrical power by rechargeable batteries. In addition to mobile communication and information technology, examples include lamps as well as power tools for drilling, grinding, screw-driving, sawing and the like. The rechargeable battery, which often is also referred to as a storage battery, made up of one or multiple cells, is in general electrically and mechanically detachably connected to the electrical or electronic device. For charging, the rechargeable battery is removed from the electrical or electronic device and mechanically and electrically connected to a charger. As an alternative, the rechargeable battery also remains connected to the device during charging, the device directly having a charger or being electrically connectable to a charger.

Rechargeable batteries are available today in different types and sizes for a plurality of applications. Corresponding to the components contained therein in each case, typical types are lead acid, nickel-cadmium (NiCd), nickel-metal hydride (NiMH), lithium-ion (Li-ion) or lithium polymer rechargeable batteries, for example. These may be used multiple times and recharged in a suitable charger. A rechargeable battery within the scope of the present invention is understood to mean a storage battery, which in addition to the actual rechargeable battery, or the actual rechargeable battery pack, may include at least one further component, such as an electronic circuit, an electrical connection and/or a locking mechanism for a mechanical connection to the electrical or electronic device or the charger.

Rechargeable lithium-ion batteries in particular must not be overcharged to prevent damage to them. Such rechargeable batteries are usually charged using a constant charge current until a cutoff voltage or an end-of-charge voltage has been reached. In a chronological sequence, the charge voltage is kept constant, and the charge current is reduced (IU charging process, constant current constant voltage (CCCV) charging process). When a drop below a certain charge current value occurs, the charging process is ended, for which current detection in the charger is required. Expensive and complex switching elements are required for this purpose, which also always have an electrical resistance, which impairs an efficiency during charging and/or discharging of the rechargeable battery.

German Patent No. 693 18 029 T2 and U.S. Pat. No. 5,477,125 teach a method for the charging of rechargeable batteries, in which, using a voltage-time function, the rechargeable battery is charged with a constant initial charge current, and the charge current is periodically interrupted to create a current-free interval of a certain duration. During this interval, a resistance-free voltage of the rechargeable battery to be charged is recorded at a certain point in time during each current-free interval and measured, and an overcharge reference voltage of the rechargeable battery is selected. The overcharge reference voltage is typical of a start of an overcharge reaction of the rechargeable battery. The charge current is periodically adjusted for this purpose in such a way that the resistance-free voltage of the rechargeable battery does not exceed the overcharge reference voltage of the rechargeable battery to prevent significant overcharging.

### SUMMARY

It is an object of the present invention to provide a method for monitoring a charge state of a rechargeable battery, in particular a charging process or a discharging process for a rechargeable battery, in particular a rechargeable lithium-ion battery, which may be carried out with a cost-effective rechargeable battery charger or a comparatively cost-effective rechargeable battery-operated device. Overcharging of the rechargeable battery should be effectively prevented, and an efficient charging process should be possible. It is furthermore an object of the present invention to provide, corresponding thereto, a computer program or a computer program product, an arithmetic unit or a processing device, and/or a rechargeable battery charger or a rechargeable battery-operated device.

The object of the present invention is achieved by a method for monitoring a charge state of a rechargeable battery, in particular by a charging or discharging process for a rechargeable battery, in particular a rechargeable lithium-ion battery; with the aid of a computer program or a computer program product; with the aid of an arithmetic unit or a processing device, preferably for a rechargeable battery charger or a rechargeable battery-operated device; and by a rechargeable battery charger or a rechargeable battery-operated device, in particular a charger, an appliance, an electromechanical tool, a lamp, a device or a vehicle.

In the monitoring method according to the present invention, a charge state, or an electrical charge or discharge current, of the rechargeable battery is inferred from a mathematical derivation or a differential coefficient of a charge or discharge voltage of the rechargeable battery. The charge state, or the charge or discharge current, of the rechargeable battery may thus be inferred from a change rate, a change acceleration, a change jump and/or one or multiple further derivations or differential coefficients of the charge or discharge voltage of the rechargeable battery. The (instantaneous) derivation of the (instantaneous) charge or discharge voltage for the (instantaneous) change rate, the (instantaneous) change acceleration, the (instantaneous) change jump and the like, takes place based on the (instantaneously) determined, ascertained or estimated charge or discharge voltage, and based on one or multiple charge or discharge voltage values which were determined, ascertained or estimated chronologically just a short time earlier, taking the time into consideration.

The monitoring method is carried out mostly or essentially throughout an entire time period of a charging or discharging process of the rechargeable battery. The instantaneous charge state, or the instantaneous charge or discharge current, of the rechargeable battery is preferably determined, ascertained or estimated based on the change rate, the change acceleration and/or the change jump, and the like, of the charge or discharge voltage of the rechargeable battery. The charge or discharge voltage is preferably measured, or the same is inferred otherwise, i.e., ascertained, determined or estimated.

The monitoring method may be carried out while an electrical charge or discharge current is flowing. The monitoring method may furthermore be carried out without influencing and/or without interrupting the charge or discharge current. Moreover, the monitoring method may be carried out without inferring a charge or discharge current, i.e., the charge or discharge current is neither measured, nor ascertained, nor determined with the aid of the monitoring method. The monitoring method according to the present invention takes place during the charging or discharging of the rechargeable battery, the charge or discharge voltage at the rechargeable battery being measured, for example, while the charge or discharge current is flowing into or flowing through the rechargeable battery, and the derivation of the charge or discharge voltage being determined, ascertained or estimated therefrom.

A control or regulation of the charge or discharge current apart from the monitoring method is preferably carried out passively, i.e., in the background. This preferably influences the charge (certain applicable charging processes) or discharge current until an end of the charging or discharging process. In the method according to the present invention, preferably no information about the charge or discharge current itself is required to estimate the charge state or the charge or discharge current. According to the present invention, means for inferring (measuring, ascertaining, determining, estimating) the charge or discharge current, or means for influencing the charge or discharge current, may be dispensed with for the monitoring method.

In one specific embodiment of the present invention, the charge (no trickle charging) or discharge current may be mostly or essentially kept constant (charging: IU charging process) while the monitoring method is carried out, but naturally outside the monitoring method itself. The charge or discharge current is preferably a charge or discharge current which is typical for a certain type of rechargeable battery, i.e., the control or regulation of the charge or discharge current takes place in the known manner. For a duration of a systematic charging or discharging process of the rechargeable battery, the monitoring method may furthermore be carried out mostly or essentially without interruption, or permanently, and, if necessary, in discrete, consecutive steps. Typical values here are from 0.1 s to 1.75 s, in particular 1 s±0.1-0.5 s.

Systematic charging or discharging of the rechargeable battery shall be understood to mean, for example, the charging of the rechargeable battery with the aid of a rechargeable battery charger (see below), the discharging of the rechargeable battery with the aid of a rechargeable battery charger, or the discharging of the rechargeable battery in a rechargeable battery-operated device (see below), i.e., an intended use of the rechargeable battery in the rechargeable battery-operated device, e.g., when illuminating surroundings with the aid of a flashlight, shall also be understood to mean a discharging of the rechargeable battery, with a preferably constant discharge current.

According to the present invention, in a range of a constant charging or discharging curve of the rechargeable battery, the charge state or the charge or discharge current of the rechargeable battery may be inferred from a comparison of a plurality of derivations of a plurality of charge or discharge voltages of the rechargeable battery. According to the present invention, the charging or discharging of the rechargeable battery may furthermore be ended when a defined value, or value range, for the derivation of the charge or discharge voltage has been reached.

According to the present invention, the charge state or the charge or discharge current of the rechargeable battery may furthermore be inferred from a charging or discharging curve which is typical for a certain type of rechargeable battery, i.e., this charging or discharging curve is used in addition to a derivation of the charge or discharge voltage.

The monitoring method according to the present invention may be a charging and/or discharging process for at least one rechargeable battery. The monitoring method may furthermore be carried out on the rechargeable battery during an intended discharging process or use of the rechargeable battery. Moreover, the monitoring method may be used on the rechargeable battery to determine, ascertain or estimate an instantaneous charge state, or an instantaneous charge or discharge current, during an intended discharging process or use of the rechargeable battery. The monitoring method may additionally be used to detect a defective rechargeable battery cell or to detect a defective rechargeable battery.

According to the present invention, a determination, ascertainment or estimation of the charge or discharge current may be used in the monitoring method, additionally an active influence of the charge or discharge current being usable, i.e., instead of only a control or regulation, e.g., to a defined charge or discharge current in the background, a charge or discharge current may be inferred according to the present invention. This measured, ascertained, determined or estimated charge or discharge current may then supplement the monitoring method. Based on a piece of information about the charge or discharge current, the behavior of the monitoring method may thus be changed. For example, a charging or discharging process may be ended in this way. It is also possible to influence an intensity of the charge or discharge current.

The computer program according to the present invention, or the computer program product according to the present invention, includes program code means which are designed to carry out a monitoring method according to the present invention when the program code means run on an arithmetic unit or a processing device, or are stored on a computer-readable data carrier. The present invention may be implemented as an (analog) method and/or as a computer program. The computer program may be carried out on a (micro)processor or a (micro- or mini-)computer and/or be stored on a data carrier or a digital storage medium.

Such a machine- or computer-readable data carrier, or such a storage medium, may be a hard drive, a ROM, EPROM, EEPROM or a flash memory, a memory chip, a diskette, a CD-ROM, a DVD, or a Blu-Ray disc, for example. The computer program may furthermore be stored in the form of firmware. The computer program may be cooperate with (if necessary, control/regulation) signals which may be provided or read out electronically, such as information about the charge or discharge voltage of the rechargeable battery, in a programmable processor or computer device or a corresponding system in such a way that a specific embodiment of the monitoring method according to the present invention may be carried out.

The arithmetic unit according to the present invention, or the processing device according to the present invention, is designed in such a way that the same is able to carry out a monitoring method according to the present invention, that the same allows a computer program according to the present invention to run and/or that the same includes a computer program product according to the present invention. For example, the arithmetic unit may be designed as an arithmetic-logic unit or as a subunit of a processing device. The processing device is designed, for example, as an electronic arithmetic device or unit, for example as a microcontroller, as a (micro- or mini-)computer, or as another device or a unit which is, of course, able to carry out or execute other tasks as well.

The rechargeable battery charger according to the present invention, or the rechargeable battery-operated device according to the present invention, is configured in such a way that the same is able to carry out a monitoring method according to the present invention, that the same includes a computer program and/or a computer program product according to the present invention and/or that the same includes an arithmetic unit according to the present invention or a processing device according to the present invention, i.e., the present invention may be implemented as a charger for charging a rechargeable battery, or as a device which is supplied with electrical power from the rechargeable battery.

The rechargeable battery charger, or the rechargeable battery-operated device, may be designed in such a way that a described method may be carried out with the aid of the same.

The rechargeable battery charger, or the rechargeable battery-operated device, may be a computer program, a computer program product, or a computer-readable data carrier, such as a described digital storage medium.

The rechargeable battery charger, or the rechargeable battery-operated device, may include an analog circuit, or an analog-to-digital converter, for measuring or otherwise inferring the charge or discharge voltage. For improved resolution of the charge or discharge voltage, furthermore a charge circuit of the rechargeable battery charger may include an additional electrical resistance. It is furthermore preferred that the rechargeable battery-operated device has a mostly or essentially linear discharge characteristic and/or a mostly or essentially constant discharge current.

A rechargeable battery charger may be, e.g., an external charger for rechargeable AA (mignon) or AAA (micro) batteries, for example, or an external charger having a charging cradle, for example for a hand-held power tool. A rechargeable battery charger may be, e.g., a charger of a rechargeable battery-operated device, the rechargeable battery-operated device or the charger thereof only having to be connected to an electrical cable for the same to function. A plug for the cable may also have a function for the charger. A rechargeable battery-operated device is an appliance, an electromechanical tool, a lamp, a device or a vehicle, for example. A rechargeable battery-operated device may be an integral part of a device, for example.

### BRIEF DESCRIPTION OF THE DRAWINGS

FIG. 1 shows a line graph of an ideal current/voltage curve of an IU charging process of a rechargeable lithium-ion battery.

FIG. 2 also shows a line graph of an actual current/voltage curve of a charger of an IU charging process of a rechargeable lithium-ion battery.

FIG. 3 shows an illustration of a charger, or of a rechargeable battery-operated device, having a rechargeable battery electrically connected thereto or therein, and associated electrical internal resistances.

FIG. 4 shows the charger, or the rechargeable battery-operated device, from FIG. 3, having an additional electrical resistance for the rechargeable battery.

### DETAILED DESCRIPTION

The present invention is described in greater detail hereafter based on specific embodiments of an IU charging process for rechargeable batteries, in particular for rechargeable lithium-ion batteries. The present invention is not limited to such specific embodiments, but is of a more fundamental nature, so that it may also be applied to a plurality of charging/discharging processes for a plurality of rechargeable batteries. The rechargeable battery, which may also be referred to as a rechargeable battery pack, may be designed as a lead, a lithium-polymer, a lithium-iron-phosphate, a lithium-titanate, a sodium-nickel chloride, a sodium-sulfur, a nickel-iron, a nickel-cadmium, a nickel-metal hydride, a nickel-hydrogen, a nickel-zinc or a tin-sulfur-lithium rechargeable battery and the like, having one or a plurality of cells connected in series and/or in parallel.

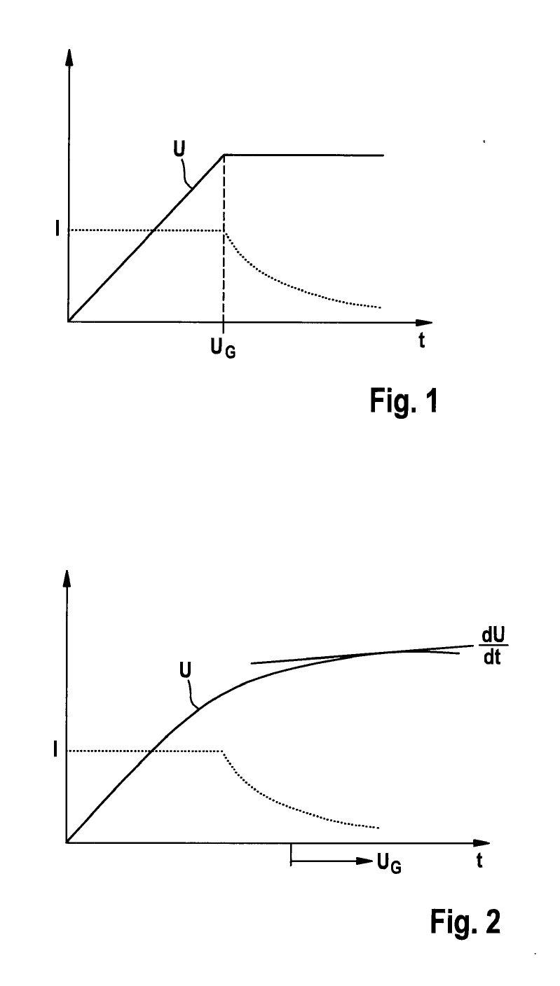

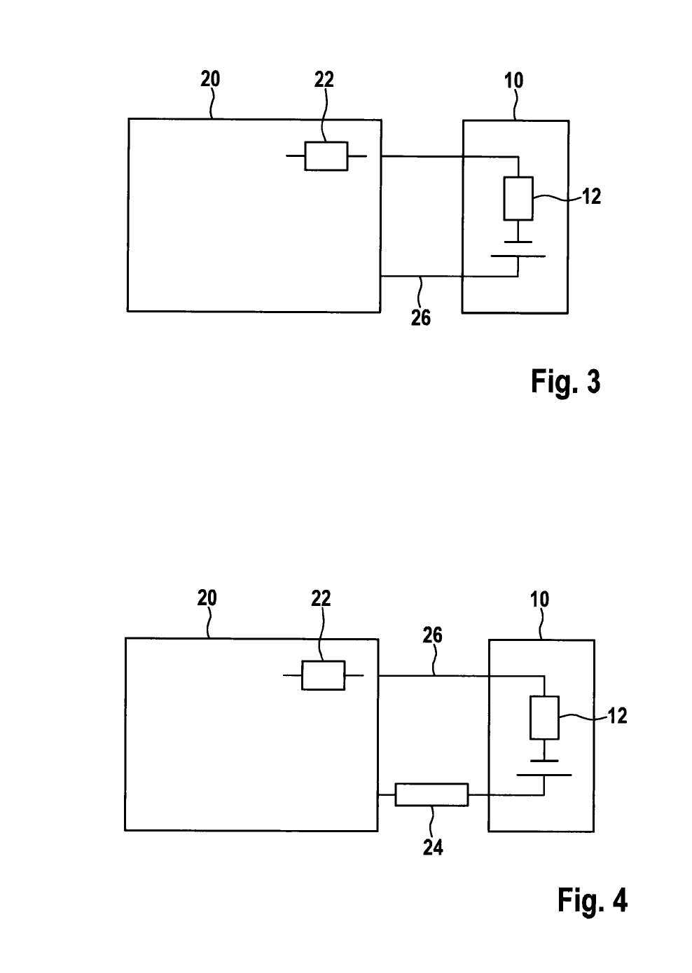

In a first phase of the ideal IU charging process illustrated in FIG. 1, rechargeable battery 10 (see FIGS. 3 and 4) is charged with a constant electrical current I, which is limited by a charger 20. Compared to a pure constant voltage charging process, a limitation of an otherwise high initial charge current I is achieved. When a selected cutoff voltage U_{G} is reached on rechargeable battery 10, a switch is made from a current to a voltage control or regulation. In a second charging phase, charging continues at a constant voltage U, the charge current I dropping automatically as the charge state of rechargeable battery 10 increases. As a criterion for ending the charging process, a drop below a selected minimal charge current I is applied in the related art.

According to the present invention, this is done with the aid of a derivation dU/dt, d²U/dt², d³U/dt³, . . . of a charge voltage U of rechargeable battery 10, see FIG. 2. This may be applied analogously to a discharge voltage U of rechargeable battery 10. For this purpose, a charge current I or discharge current I of rechargeable battery 10 is neither detected nor interrupted. According to the present invention, charge current I may be estimated without requiring a current measurement for this purpose. In this way, costs may be reduced for charger 20, for example. Instead of a direct current measurement, in the present invention a level of charge current I is estimated at least via a change rate dU/dt of charge or rechargeable battery voltage U, or a charging process is influenced based on a characteristic feature of a behavior of this change rate dU/dt.

Measuring, determining, ascertaining or estimating of rechargeable battery voltage U, i.e., inferring of rechargeable battery voltage U, is carried out in relative terms, which allows a use of inexpensive analog-to-digital converters or of analog measuring circuits without a comparatively very precise voltage reference—for example in the μV range. In addition or as an alternative, a change acceleration d²U/dt², a change jump d³U/dt³ and/or one or multiple further derivations of rechargeable battery voltage U may be applied, in addition to change rate dU/dt.

During charging of rechargeable battery 10, voltage U at rechargeable battery 10 remains theoretically constant after a cutoff voltage U_{G} has been reached (see FIG. 1). However, in reality (FIG. 2), cutoff voltage U_{G} approaches a real cutoff voltage U_{G} as charge current I decreases. This is caused by an internal resistance 12 of rechargeable battery 10, or of its cells, and an internal resistance 22 of a charging circuit 26 of charger 20. According to the present invention, the charging process is ended when a predetermined value, or value range, of change rate dU/dt is reached and/or when a predetermined value, or value range, of a further derivation d²U/dt², d³U/dt³, . . . of rechargeable battery voltage U is reached. For an individual cell of a rechargeable battery 10, this change rate dU/dt is 1-2 mV/min to 200 mV/min. Converted to ten cells per rechargeable battery 10, this results in a change rate which may range between 10-20 mV/min and 2 V/min.

With the aid of an additional resistance 24 (FIG. 4) in charge circuit 26 of charger 20, a measuring time t for change rate dU/dt of rechargeable battery voltage U may be increased, in particular the time of a phase having a constant charge voltage U being extended. An influence of an internal resistance 12 of rechargeable battery 10 on change rate dU/dt of rechargeable battery voltage U is thus reduced. Change rate dU/dt of charge voltage U may additionally be used to estimate the charge state of rechargeable battery 10, which may be used for a charge level indicator, for example.

Moreover, defects of the rechargeable battery cells or of defective rechargeable batteries 10 may be detected by evaluating change rate dU/dt of charge voltage U or discharge voltage U. Charge current I is not detected and not influenced. Moreover, various change rates dU/dt, or a further derivation d²U/dt², d³U/dt³, . . . thereof, may be applied for estimating the charge state of rechargeable battery 10, in particular in a range of a constant current charging phase (see FIG. 2). In particular inflection points in a curve of rechargeable battery voltage U during the constant current charging phase are to be evaluated.

A measurement of change rate dU/dt, or a further derivation d²U/dt², d³U/dt³, . . . of rechargeable battery voltage U, may be carried out both via an analog-to-digital converter or with the aid of an analog circuit. Charger 20, or rechargeable battery-operated device 20, furthermore preferably includes a monitoring device, which ascertains a physical variable of the rechargeable battery. For example, the physical variable may be a temperature of rechargeable battery 10. If the physical variable deviates from a predefined value or range, the monitoring device interrupts or changes a charging or discharging process of rechargeable battery 10.

The present invention involves a charging or discharging process, in particular for rechargeable lithium-ion batteries 10, including a measurement of a change rate dU/dt of a rechargeable battery voltage U and/or of further derivations d²U/dt², d³U/dt³, . . . of rechargeable battery voltage U. In the method, a charge current I may be estimated based on change rate dU/dt and/or further derivations d²U/dt², d³U/dt³, . . . of rechargeable battery voltage U. The estimation is carried out in relative terms with the aid of voltage detection. When a defined value has been reached, e.g., a certain change rate dU/dt of rechargeable battery voltage U, the charging or discharging process is ended.

The monitoring method according to the present invention allows charge current I to be estimated or calculated from the derivation or derivations dU/dt, d²U/dt², d³U/dt³, . . . of rechargeable battery voltage U, without measuring the charge current. This is advantageous when additional information is available, which together with charge current I thus ascertained promises new findings. If this is not the case, charge current I may be substituted by the monitoring method according to the present invention, i.e., instead of charge current I, a different variable is used, i.e., derivation(s) dU/dt, d²U/dt², d³U/dt³, . . . of rechargeable battery voltage U, this derivation or these derivations not necessarily having to have a similarity relationship with charge current I. Naturally, it is also possible to use both.

The above explanations refer to a charging process of rechargeable battery 10 with electrical energy; however, it is possible to apply these explanations vice versa to a discharging process of rechargeable battery 10. The present invention may be applied, e.g., to rechargeable batteries 10 of small appliances 20, such as electrical toothbrushes 20 or razors 20; mobile telephones 20; lamps 20, such as flashlights 20; toys 20; cordless tools 20, such as hand-held power tools 20; notebooks 20; computers 20, all the way to batteries 10, i.e., rechargeable batteries 10, for electric drives 20; electromobiles 20; forklifts 20; electric vehicles 20, and hybrid vehicles 20, and the like.

One criterion for terminating a charging or discharging process is, e.g., a certain slope of an increase in rechargeable battery voltage U during a certain time period, which is ascertainable with the aid of change rate dU/dt and/or further derivations d²U/dt², d³U/dt³, . . . of rechargeable battery voltage U. If, e.g., change rate dU/dt of rechargeable battery voltage U is lower during a charging process than a certain value, or value range (minimal slope), it may be assumed that rechargeable battery 10 in question has reached a charge state which is at its capacity limit. If change rate dU/dt of rechargeable battery voltage U is greater during a discharging process than a certain value, or value range (maximal slope), it may be assumed that rechargeable battery 10 in question has been essentially fully discharged.

What is claimed is:

1. A method for monitoring a charge state of a rechargeable battery, comprising:
inferring one of a charge state, a charge current, and a discharge current of the rechargeable battery by a derivation of one of a charge voltage and a discharge voltage of the rechargeable battery.

2. The monitoring method as recited in claim 1, wherein the charge state of the rechargeable battery is inferred from at least one of a change rate, a change acceleration, a change jump, and at least one further derivation of one of the charge voltage and the discharge voltage of the rechargeable battery.

3. The monitoring method as recited in claim 1, wherein the monitoring method is carried out at least one of:
while one of an electrical charge current and a discharge current is flowing;
without at least one of influencing and interrupting the one of the charge current and the discharge current; and
without inferring one of the charge current and the discharge current.

4. The monitoring method as recited in claim 1, wherein the one of the charge current and the discharge current is kept constant while the monitoring method is carried out, the one of the charge current and the discharge current being one of a charge current and a discharge current which is typical for a certain type of rechargeable battery.

5. The monitoring method as recited in claim 1, wherein, for a duration of one of a systematic charging process and systematic discharging process of the rechargeable battery, the monitoring method is carried out without interruption and in discrete, chronologically consecutive steps.

6. The monitoring method as recited in claim 1, wherein, in a range of one of a constant charging curve and a discharging curve of the rechargeable battery, the charge state of the rechargeable battery is inferred from a comparison of multiple derivations of one of multiple charge voltages and discharge voltages of the rechargeable battery.

7. The monitoring method as recited in claim 1, wherein one of a charging process and a discharging process of the rechargeable battery is ended when one of a defined value and a value range for the derivation of the one of the charge voltage and the discharge voltage has been reached.

8. The monitoring method as recited in claim 1, wherein at least one of:
the charge state of the rechargeable battery is further inferred from a charging or discharging curve which is typical for a certain type of rechargeable battery;
the monitoring method is a charging and/or discharging process for at least one rechargeable battery;
the monitoring method is carried out on the rechargeable battery during an intended discharging process or use of the rechargeable battery;
the monitoring method is used on the rechargeable battery to determine, ascertain or estimate an instantaneous charge state during an intended discharging process or use of the rechargeable battery;
the monitoring method is used to detect a defective rechargeable battery cell or to detect a defective rechargeable battery;
furthermore a determination, ascertainment or estimation of the charge current or discharge current is used in the monitoring method; and
furthermore an active influence of the charge current or discharge current is used in the monitoring method.

9. A computer program or a computer program product including program code means, which are designed to carry out a monitoring method when the program code means run on an arithmetic unit or a processing device, or are stored on a computer-readable data carrier, the method being for monitoring a charge state of a rechargeable battery, and comprising:
inferring one of a charge state, a charge current, and a discharge current of the rechargeable battery by a derivation of one of a charge voltage and a discharge voltage of the rechargeable battery.

10. An arithmetic unit or a processing device, for a rechargeable battery charger or a rechargeable battery-operated device, which is designed in such a way that the arithmetic unit or the processing device is able to carry out a method for monitoring a charge state of a rechargeable battery, comprising:
inferring one of a charge state, a charge current, and a discharge current of the rechargeable battery by a derivation of one of a charge voltage and a discharge voltage of the rechargeable battery.

11. A rechargeable battery charger, or a rechargeable battery-operated device, wherein the rechargeable battery charger, or the rechargeable battery-operated device, is configured in such a way that it is able to carry out a method for monitoring a charge state of a rechargeable battery, comprising: inferring one of a charge state, a charge current, and a discharge current of the rechargeable battery by a derivation of one of a charge voltage and a discharge voltage of the rechargeable battery, the rechargeable battery charger, or the rechargeable battery-operated device, includes at least one of a computer program or a computer program product, and an arithmetic unit or a processing device.

12. The rechargeable battery charger, or a rechargeable battery-operated device, as recited in claim 11, wherein at least one of:
the rechargeable battery charger, or the rechargeable battery-operated device, includes an analog circuit, or an analog-to-digital converter, for measuring or for otherwise inferring the charge voltage or discharge voltage;
the rechargeable battery charger includes an additional electrical resistance in a charge circuit;
the rechargeable battery-operated device has a mostly or essentially linear discharge characteristic; and
the rechargeable battery-operated device has a mostly or essentially constant discharge current.

13. The monitoring method as recited in claim 1, wherein the method pertains to one of a charging or discharging process for a rechargeable battery, and wherein the rechargeable battery includes a rechargeable lithium-ion battery.

14. The rechargeable battery charger, or the rechargeable battery-operated device as recited in claim 11, wherein the device includes one of a charger, an appliance, an electromechanical tool, a lamp, and a vehicle.
